(19) United States
(12) Patent Application Publication
(10) Pub. No.: US 2025/0255067 A1
(43) Pub. Date: Aug. 7, 2025

(54) DISPLAY DEVICE AND METHOD OF MANUFACTURING THE SAME

(71) Applicant: Samsung Display Co., Ltd., Yongin-Si (KR)

(72) Inventors: Seungwon Park, Yongin-si (KR); Kyungsig Lee, Yongin-si (KR)

(21) Appl. No.: 19/026,785

(22) Filed: Jan. 17, 2025

(30) Foreign Application Priority Data
Feb. 1, 2024 (KR) 10-2024-0016199

(51) Int. Cl. H10H 29/37; H10H 29/01; H10H 29/24; H10H 29/80; H10H 29/851

(52) U.S. Cl. CPC H10H 29/37; H10H 29/012; H10H 29/24; H10H 29/8421; H10H 29/851

(57) ABSTRACT

A display device is disclosed that includes a substrate, a bank layer disposed on the substrate, and a reflective layer disposed on a side surface of the bank layer and in contact with a light-transmitting layer, a second color quantum dot layer or a third color quantum dot layer, wherein the bank layer and the reflective layer together have a length of 1 μm or less in a direction parallel to the substrate.

### CROSS-REFERENCE TO RELATED APPLICATION

This application is claims priority under 35 U.S.C. § 119 to Korean Patent Application No. 10-2024-0016199, filed on Feb. 1, 2024, in the Korean Intellectual Property Office, the disclosure of which is incorporated by reference herein in its entirety.

### BACKGROUND

### 1. Field

The present disclosure relates to a display device and a method of manufacturing the display device.

### 2. Description of the Related Art

A display device visually displays image by receiving data corresponding to the image. The display device may be used as a display unit for small products, such as mobile phones, or as a display unit for large products, such as televisions.

The display device may include a liquid crystal display device that does not emit light by itself but uses light from a backlight, or a light-emitting display device that includes a display element capable of emitting light and the display element may include an emission layer.

### SUMMARY

The present disclosure includes a display device and a method of manufacturing the display device.

Additional aspects will be set forth in the description which follows and will be apparent from the description.

According to an embodiment, a display device comprises a substrate, a bank layer disposed on the substrate, and a reflective layer disposed on a side surface of the bank layer and in contact with a light-transmitting layer, a second color quantum layer or a third color quantum dot layer, wherein the bank layer and the reflective layer together have a length of 1 μm or less in a direction parallel to the substrate.

According to an embodiment, the reflective layer may be in contact with the side surface of the bank layer.

According to an embodiment, the bank layer may include an inorganic material.

According to an embodiment, the bank layer may include at least one of silicon nitride (SiNₓ) or silicon oxide (SiOₓ).

According to an embodiment, the reflective layer may include metal.

According to an embodiment, the reflective layer may include at least one of aluminum (Al), silver (Ag), or titanium (Ti).

According to an embodiment, an upper surface of the bank layer may be inclined.

According to an embodiment, a method of manufacturing a display device comprises preparing a substrate, depositing a bank layer forming material on the substrate, forming a bank layer by patterning the bank layer forming material, depositing a reflective layer forming material on the bank layer, and forming a reflective layer disposed on a side surface of the bank layer by etching at least a portion of the reflective layer forming material, and forming a light-transmitting layer, a second color quantum dot layer or a third color quantum dot layer in a spacing area between two adjacent reflective layers, wherein the reflective layer is contact with the light-transmitting layer, the second color quantum dot layer or the third color quantum dot layer, and wherein the bank layer and the reflective layer together have a length of 1 μm or less in a direction parallel to the substrate.

According to an embodiment, the forming the reflective layer by etching at least the portion of the reflective layer forming material may comprise forming the reflective layer by anisotropically etching a portion of the reflective layer forming material, wherein the portion of the reflective layer forming material is disposed parallel to the substrate.

According to an embodiment, the forming the bank layer by patterning the bank layer forming layer may comprise disposing a hard mask on the bank layer forming material, forming a sidewall on the hard mask, and forming the bank layer by etching a portion of the bank layer forming material, wherein the portion of the bank layer forming material is not covered by the sidewall.

According to an embodiment, the forming the bank layer by etching the portion of the bank layer forming material may comprise etching a portion of the hard mask on which the sidewall is not disposed.

According to an embodiment, the forming the sidewall on the hard mask may comprise forming a sacrificial layer on the hard mask, depositing a sidewall forming material on the sacrificial layer, forming the sidewall by anisotropically etching a portion of the sidewall forming material, wherein the portion of the sidewall forming material is disposed parallel to the substrate, and removing the sacrificial layer.

According to an embodiment, the forming the sacrificial layer on the hard mask may comprise depositing a sacrificial layer forming material on the hard mask, depositing a photoresist on at least a portion of the sacrificial layer forming material, and forming the sacrificial layer by etching a portion of the sacrificial layer forming material, wherein the photoresist is not disposed on the portion of the sacrificial layer forming material.

According to an embodiment, the bank layer may include an inorganic material.

According to an embodiment, the bank layer may include at least one of silicon nitride (SiNₓ) or silicon oxide (SiOₓ).

According to an embodiment, the reflective layer may include at least one of aluminum (Al), silver (Ag), or titanium (Ti).

According to an embodiment, a method of manufacturing a display device comprises preparing a substrate, forming a sacrificial layer on the substrate, forming a bank layer using the sacrificial layer, and forming a reflective layer disposed on a side surface of the bank layer, and forming a light-transmitting layer, a second color quantum dot layer or a third color quantum dot layer in a spacing area between two adjacent reflective layers, wherein the reflective layer is in contact with the light-transmitting layer, the second color quantum dot layer or the third color quantum dot layer, and wherein the bank layer and the reflective layer together have a length of 1 μm or less in a direction parallel to the substrate.

According to an embodiment, an upper surface of the bank layer may be inclined.

According to an embodiment, the forming the sacrificial layer on the substrate may comprise depositing a sacrificial layer forming material on the substrate, depositing a photoresist on at least a portion of the sacrificial layer forming material, and forming the sacrificial layer by etching at least a portion of the sacrificial layer forming material, wherein the photoresist is not disposed on the portion of the sacrificial layer forming material.

According to an embodiment, the forming the bank layer may comprise depositing a bank layer forming material on the sacrificial layer, and forming the bank layer by anisotropically etching a portion of the bank layer forming material, wherein the portion of the bank layer forming material is disposed parallel to the substrate.

### BRIEF DESCRIPTION OF THE DRAWINGS

The above and other aspects, features, and advantages of the present disclosure will become more apparent by reference to the following description taken in conjunction with the accompanying drawings.

FIG. 1 is a schematic perspective view of a display device according to an embodiment.

FIG. 2 is a schematic cross-sectional view of each pixel of a display device according to an embodiment.

FIG. 3 illustrates optical portions of a color conversion-transmissive layer of FIG. 2.

FIG. 4 is an equivalent circuit diagram representing a light-emitting diode and a pixel circuit electrically connected to the light-emitting diode, which are included in a display device according to an embodiment.

FIGS. 5 and 6 are schematic cross-sectional views of the display device taken along a line I-I′ of FIG. 1, according to embodiments.

FIGS. 7 to 13 are cross-sectional views schematically illustrating a method of manufacturing the display device shown in FIG. 5, according to an embodiment.

FIGS. 14 to 19 are cross-sectional views schematically illustrating a method of manufacturing the display device shown in FIG. 6, according to an embodiment.

### DETAILED DESCRIPTION

Hereinafter, specific embodiments of the present disclosure are explained in detail with reference to the accompanying drawings. Like numerals refer to like elements throughout. In this regard, embodiments of the present disclosure may have different forms and should not be construed as being limited to the descriptions set forth herein. Accordingly, the embodiments are merely described below, by referring to the drawings, to explain aspects of the present disclosure. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

As the present disclosure allows for various changes and can have numerous embodiments, particular embodiments will be illustrated in the drawings and described in detail in the written description. The attached drawings for illustrating embodiments of the present disclosure are referred to in order to gain a sufficient understanding, the merits thereof, and the features accomplished by the present disclosure. However, it should be noted that the embodiments of the present disclosure may have different forms and should not be construed as being limited to the descriptions set forth herein.

Embodiments of the present disclosure will be described below in more detail with reference to the accompanying drawings, wherein the same or corresponding elements are denoted by the same reference numerals throughout, and a repeated description thereof is omitted.

It will be understood that although the terms “first,” “second,” etc. may be used herein to describe various components, these components should not be limited by these terms. These components are only used to distinguish one component from another.

As used herein, the singular forms “a,” “an,” and “the” are intended to include the plural forms as well, unless the context clearly indicates otherwise.

It will be further understood that the terms “includes”, “has”, “including”, or “having” used herein specify the presence of stated features or components, but do not preclude the presence or addition of one or more other features or components.

It will be understood that when a layer, region, or component is referred to as being “formed on” another layer, region, or component, it can be directly or indirectly formed on the other layer, region, or component. That is, for example, intervening layers, regions, or components may be present.

Sizes of elements in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the following embodiments, when layers, regions, or components are connected to each other, the layers, the regions, or the components may be directly connected to each other, or another layer, another region, or another component may be interposed between the layers, the regions, or the components and thus the layers, the regions, or the components may be indirectly connected to each other. For example, in the following embodiments, when layers, regions, or components are electrically connected to each other, the layers, the regions, or the components may be directly electrically connected to each other, or another layer, another region, or another component may be interposed between the layers, the regions, or the components and thus the layers, the regions, or the components may be indirectly electrically connected to each other.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

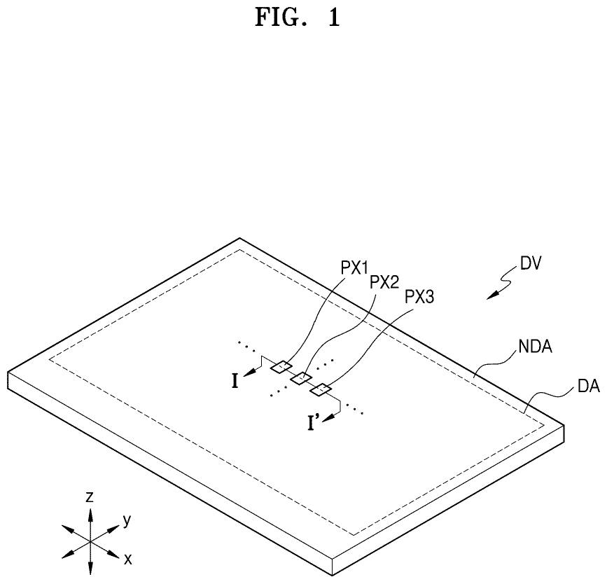

FIG. 1 is a schematic perspective view of a display device DV according to an embodiment.

Referring to FIG. 1, the display device DV may include a display area DA and a non-display area NDA outside the display area DA. The display device DV may provide an image through an array of a plurality of pixels that are two-dimensionally arranged on an x-y plane in the display area DA. The plurality of pixels may include a first pixel PX1, a second pixel PX2, and a third pixel PX3. The first pixel PX1 may be a blue pixel, the second pixel PX2 may be a green pixel, and the third pixel PX3 may be a red pixel.

The first pixel PX1, the second pixel PX2, and the third pixel PX3 may emit blue light, green light, and red light, respectively, and the display device DV may provide images by using light emitted from the pixels.

The non-display area NDA is an area that does not provide an image and may entirely surround the display area DA. A driver or a main voltage line configured to provide an electrical signal or power to pixel circuits of the plurality of pixels may be arranged in the non-display area NDA. The non-display area NDA may include a pad, which is an area to which an electronic device or a printed circuit board may be electrically connected.

The display area DA may have a polygonal shape including a quadrangle, as shown in FIG. 1. For example, the display area DA may have a rectangular shape in which a horizontal length is greater than a vertical length, a rectangular shape in which a horizontal length is less than a vertical length, or a square shape. In other embodiments, the display area DA may have various shapes, such as an ellipse or a circle.

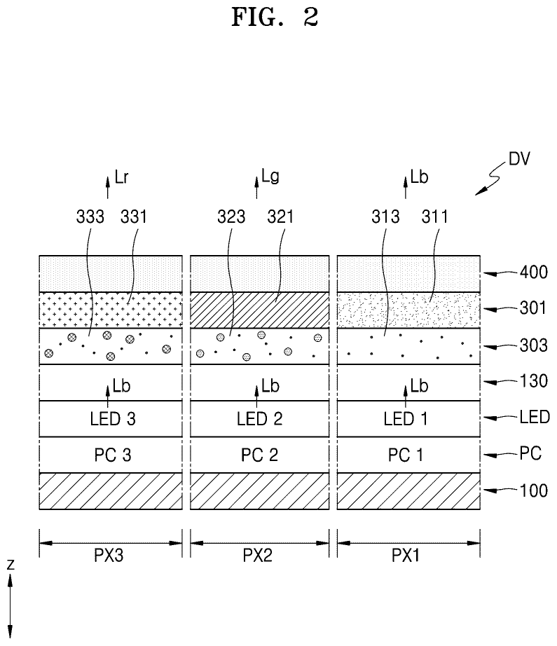

FIG. 2 is a schematic cross-sectional view of each pixel of a display device DV according to an embodiment.

Referring to FIG. 2, the display device DV may include a circuit layer PC on a lower substrate 100. The circuit layer PC may include first to third pixel circuits PC1, PC2, and PC3, and the first to third pixel circuits PC1, PC2, and PC3 may be electrically connected to first to third light-emitting diodes LED1, LED2, and LED3 of a light-emitting diode layer LED, respectively.

Each of the first to third light-emitting diodes LED1, LED2, and LED3 may be an organic light-emitting diode including an organic material. In other embodiments, each of the first to third light-emitting diodes LED1, LED2, and LED3 may be an inorganic light-emitting diode including an inorganic material. The inorganic light-emitting diode may include a PN junction diode including inorganic semiconductor-based materials. When a voltage is applied to the PN junction diode in a forward direction, holes and electrons may be injected, and energy generated by recombination of the holes and the electrons may be converted into light energy to emit light of a predetermined color. The inorganic light-emitting diode described above may have a width of several to several hundred micrometers or several to several hundred nanometers. In other embodiments, each of the first to third light-emitting diodes LED1, LED2, and LED3 may be a light-emitting diode including quantum dots. As described above, an emission layer of each of the first to third light-emitting diodes LED1, LED2, and LED3 may include an organic material, include an inorganic material, include quantum dots, include an organic material and quantum dots, or include an inorganic material and quantum dots.

The first to third light-emitting diodes LED1, LED2, and LED3 may emit light of the same color. For example, light (e.g., blue light Lb) emitted from the first to third light-emitting diodes LED1, LED2, and LED3 may pass through an encapsulation layer 130 disposed on the light-emitting diode layer LED and pass through a color conversion-transmissive layer 303.

The color conversion-transmissive layer 303 may include optical portions that transmit light (e.g., the blue light Lb) emitted from the light-emitting diode layer LED with or without converting the color of the light. For example, the color conversion-transmissive layer 303 may include quantum dot layers 323 and 333 that convert the light (e.g., the blue light Lb) emitted from the light-emitting diode layer LED into light of another color, and a light-transmitting layer 313 that transmits the light (e.g., the blue light Lb) emitted from the light-emitting diode layer LED without converting the color of the light. The color conversion-transmissive layer 303 may include a third color quantum dot layer 333 corresponding to the red pixel, a second color quantum dot layer 323 corresponding to the green pixel, and the light-transmitting layer 313 corresponding to the blue pixel. The third color quantum dot layer 333 may convert the blue light Lb into the red light Lr, and the second color quantum dot layer 323 may convert the blue light Lb into the green light Lg. The light-transmitting layer 313 may allow the blue light Lb to pass therethrough without converting the blue light Lb.

A color filter layer 301 may be disposed on the color conversion-transmissive layer 303. The color filter layer 301 may include first to third color filter layers 311, 321, and 331 having different colors. For example, the first color filter layer 311 may be a blue color filter layer, the second color filter layer 321 may be a green color filter layer, and the third color filter layer 331 may be a red color filter layer.

The color-converted light and the transmitted light from the color conversion-transmissive layer 303 may undergo an enhancement in color purity as they pass through the first to third color filters 311, 321 and 331, respectively. Also, the color filter layer 301 may prevent or reduce external light (e.g., light incident from the outside of the display device DV toward the display device DV) from being reflected and recognized by a user.

An upper substrate 400 may be provided on the color filter layer 301. The upper substrate 400 may include glass or a light-transmitting organic material. For example, the upper substrate 400 may include a light-transmitting organic material, such as acrylic resin.

As an embodiment, the upper substrate 400 may be a type of substrate, and after the color filter layer 301 and the color conversion-transmissive layer 303 are formed on the upper substrate 400, the color conversion-transmissive layer 303 may be disposed to face the encapsulation layer 130.

In other embodiments, after the color conversion-transmissive layer 303 and the color filter layer 301 are sequentially formed on the encapsulation layer 130, the upper substrate 400 may be directly disposed on the color filter layer 301. Although not shown in the drawings, another optical film, such as an anti-reflection (AR) film, may be disposed on the upper substrate 400.

The display device DV having the above-described structure may include a television, a billboard, a screen for a movie theater, a monitor, a tablet personal computer (PC), a laptop computer, or the like.

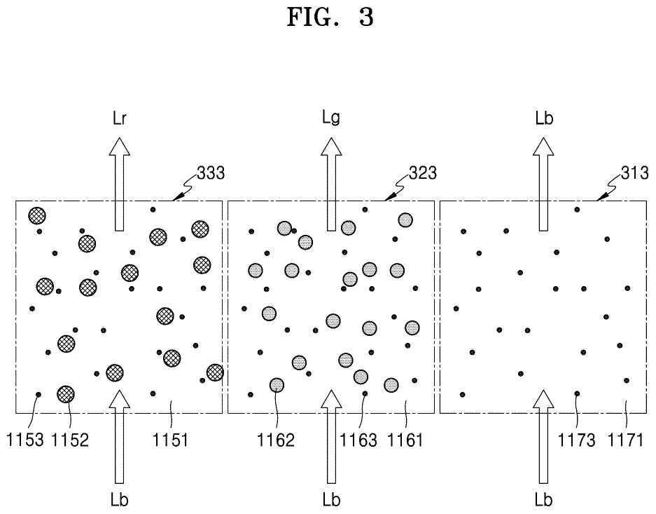

FIG. 3 illustrates optical portions of the color conversion-transmissive layer 303 of FIG. 2.

Referring to FIG. 3, the third color quantum dot layer 333 may convert incident blue light Lb into red light Lr. As shown in FIG. 3, the third color quantum dot layer 333 may include a first photosensitive polymer 1151, and third color quantum dots 1152 and first scattering particles 1153 dispersed in the first photosensitive polymer 1151.

The third color quantum dots 1152 may be excited by the blue light Lb to isotropically emit the red light Lr having a longer wavelength than the blue light Lb. The first photosensitive polymer 1151 may be an organic material having light transmittance. The first scattering particles 1153 may scatter blue light Lb that is not absorbed by the third color quantum dots 1152 in order for more third color quantum dots 1152 to be excited, thereby increasing color conversion efficiency. The first scattering particles 1153 may be, for example, titanium oxide (TiO₂) or metal particles. The third color quantum dots 1152 may be selected from a Group II-VI compound, a Group III-V compound, a Group IV-VI compound, a Group IV element, a Group IV compound, and a combination thereof.

The second color quantum dot layer 323 may convert incident blue light Lb into green light Lg. As shown in FIG. 3, the second color quantum dot layer 323 may include a second photosensitive polymer 1161, and second color quantum dots 1162 and second scattering particles 1163 dispersed in the second photosensitive polymer 1161.

The second color quantum dots 1162 may be excited by the blue light Lb to isotropically emit the green light Lg having a longer wavelength than the blue light Lb. The second photosensitive polymer 1161 may be an organic material having light transmittance.

The second scattering particles 1163 may scatter blue light Lb that is not absorbed by the second color quantum dots 1162 in order for more second color quantum dots 1162 to be excited, thereby increasing color conversion efficiency. The second scattering particles 1163 may be, for example, titanium oxide (TiO₂) or metal particles. The second color quantum dots 1162 may be selected from a Group II-VI compound, a Group III-V compound, a Group IV-VI compound, a Group IV element, a Group IV compound, and a combination thereof.

In an embodiment, the third color quantum dots 1152 and the second color quantum dots 1162 may include the same material. In this case, the sizes of the third color quantum dots 1152 may be greater than the sizes of the second color quantum dots 1162.

The light-transmitting layer 313 may transmit the blue light Lb without converting the blue light Lb incident to the light-transmitting layer 313. As shown in FIG. 3, the light-transmitting layer 313 may include a third photosensitive polymer 1171 in which third scattering particles 1173 are dispersed. The third photosensitive polymer 1171 may be an organic material having light transmittance, such as a silicone resin or an epoxy resin, and may be the same material as the first and second photosensitive polymers 1151 and 1161. The third scattering particles 1173 may scatter and emit blue light Lb, and may include the same material as the first and second scattering particles 1153 and 1163.

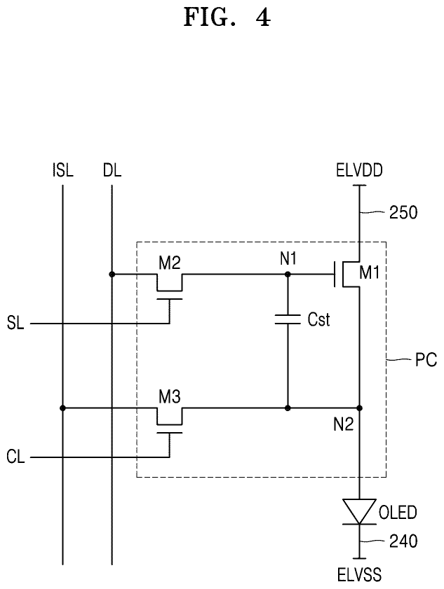

FIG. 4 is an equivalent circuit diagram representing a light-emitting diode OLED and a pixel circuit PC electrically connected to the light-emitting diode OLED, which are included in a display device according to an embodiment.

Referring to FIG. 4, a first electrode (e.g., an anode) of the light-emitting diode OLED may be connected to the pixel circuit PC, and a second electrode (e.g., a cathode) of the light-emitting diode OLED may be connected to a common voltage line 240 configured to provide a common power supply voltage ELVSS. The light-emitting diode OLED may emit light with a luminance corresponding to the amount of current supplied from the pixel circuit PC.

The light-emitting diode OLED of FIG. 4 may correspond to each of the first to third light-emitting diodes LED1, LED2, and LED3 shown in FIG. 2, and the pixel circuit PC of FIG. 4 may correspond to each of the first to third pixel circuits PC1, PC2, and PC3 shown in FIG. 2.

The pixel circuit PC may control the amount of current flowing from a driving power supply voltage ELVDD to the common power supply voltage ELVSS via the light-emitting diode OLED in response to a data signal. The pixel circuit PC may include a driving transistor M1, a switching transistor M2, a sensing transistor M3, and a storage capacitor Cst.

Each of the driving transistor M1, the switching transistor M2, and the sensing transistor M3 may be an oxide semiconductor thin-film transistor including a semiconductor layer made of an oxide semiconductor, or a silicon semiconductor thin-film transistor including a semiconductor layer made of polysilicon. Each of the driving transistor M1, the switching transistor M2, and the sensing transistor M3 may include a source electrode (or a source region) and a drain electrode (or a drain region).

A source electrode (or a source region) of the driving transistor M1 may be connected to a driving voltage line 250 configured to supply the driving power supply voltage ELVDD, and a drain electrode (or a drain region) of the driving transistor M1 may be connected to the first electrode (e.g., the anode) of the light-emitting diode OLED. A gate electrode of the driving transistor M1 may be connected to a first node N1. The driving transistor M1 may be configured to control the amount of current flowing through the light-emitting diode OLED from the driving power supply voltage ELVDD in response to the voltage of the first node N1. However, the position of the source electrode (or the source region) of the driving transistor M1 and the position of the drain electrode (or the drain region) of the driving transistor M1 may be interchanged.

The switching transistor M2 may be a transistor for switching. A source electrode (or a source region) of the switching transistor M2 may be connected to a data line DL, and a drain electrode (or a drain region) of the switching transistor M2 may be connected to the first node N1. A gate electrode of the switching transistor M2 may be connected to a scan line SL. The switching transistor M2 may be configured to be turned on when a scan signal is supplied to the scan line SL and may electrically connect the data line DL and the first node N1. However, the position of the source electrode (or the source region) of the switching transistor M2 and the position of the drain electrode (or the drain region) of the switching transistor M2 may be interchanged.

The sensing transistor M3 may be a transistor for initialization or a transistor for sensing. A drain electrode (or a drain region) of the sensing transistor M3 may be connected to a second node N2, and a source electrode (or a source region) of the sensing transistor M3 may be connected to a sensing line ISL. A gate electrode of the sensing transistor M3 may be connected to a control line CL. However, the position of the source electrode (or the source region) of the sensing transistor M3 and the position of the drain electrode (or the drain region) of the sensing transistor M3 may be interchanged.

The storage capacitor Cst may be connected between the first node N1 and the second node N2. For example, a first capacitor electrode of the storage capacitor Cst may be connected to the gate electrode of the driving transistor M1, and a second capacitor electrode of the storage capacitor Cst may be connected to the first electrode (e.g., the anode) of the light-emitting diode OLED.

Although FIG. 4 illustrates an example in which the driving transistor M1, the switching transistor M2, and the sensing transistor M3 are NMOS transistors, the present disclosure is not limited thereto. For example, at least one of the driving transistor M1, the switching transistor M2, and the sensing transistor M3 may be a PMOS transistor.

Although three transistors are illustrated in FIG. 4, the present disclosure is not limited thereto. The pixel circuit PC may include four or more transistors.

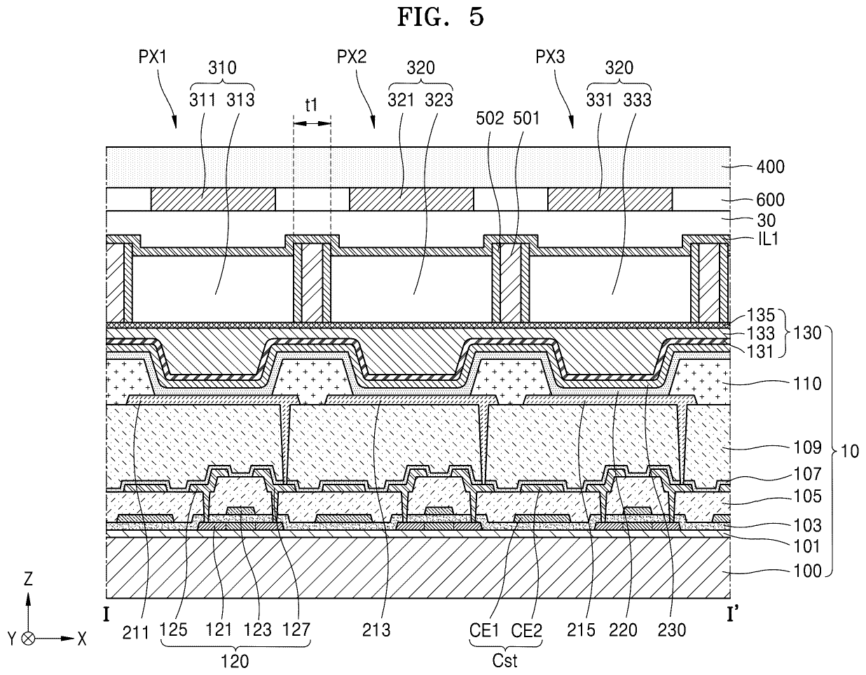

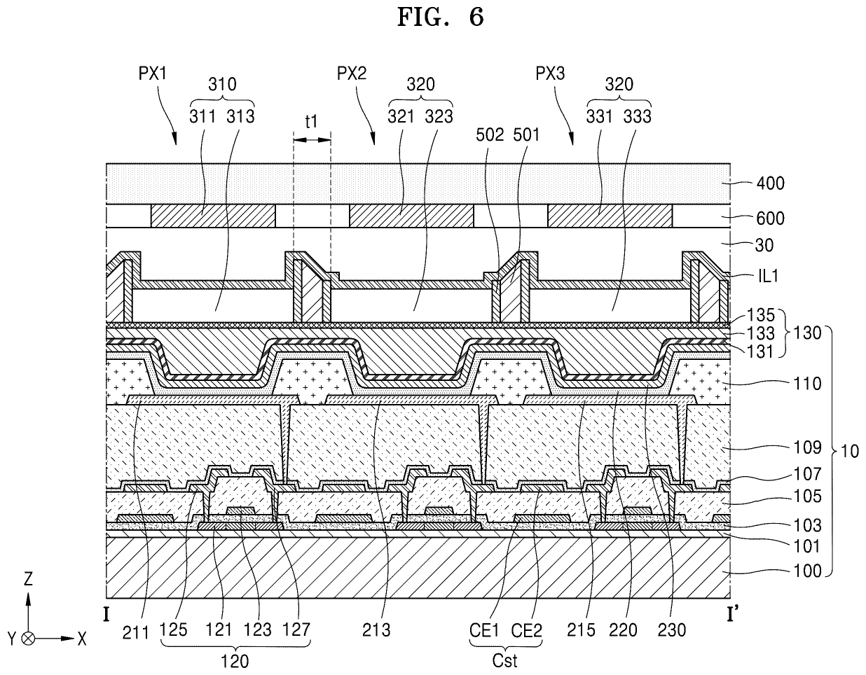

FIGS. 5 and 6 are schematic cross-sectional views of the display device DV taken along line a I-I′ of FIG. 1, according to embodiments.

Referring to FIGS. 5 and 6, the display device DV according to an embodiment may include a display unit 10, second and third quantum dot layers 323 and 333, a light-transmitting layer 313, first to third color filter layers 311, 321, and 331, and an adhesive layer 30.

The display unit 10 may include a lower substrate 100. The lower substrate 100 may include glass, metal, ceramic, or a material that is flexible or bendable. When the lower substrate 100 is flexible or bendable, the lower substrate 100 may include a polymer resin, such as polyethersuphone, polyacrylate, polyetherimide, polyethylene naphthalate, polyethylene terephthalate, polyphenylene sulfide, polyarylate, polyimide, polycarbonate, or cellulose acetate propionate. The lower substrate 100 may have a single-layered or multi-layered structure including the aforementioned material. The lower substrate 100 may have a multi-layered structure comprising two layers including a polymer resin and a barrier layer including an inorganic material (such as silicon oxide, silicon nitride, or silicon oxynitride) interposed between the two layers. However, various modifications may be possible.

A buffer layer 101 may be formed on the lower substrate 100. The buffer layer 101 may include an inorganic material, such as silicon oxide, silicon nitride, or silicon oxynitride, and may be formed in a single layer or multilayer. This buffer layer 101 may increase the smoothness of the upper surface of the lower substrate 100, or may prevent or reduce impurities or moisture from the outside of the lower substrate 100 from penetrating into a semiconductor layer 121 of a thin-film transistor 120.

A pixel circuit may be disposed on the buffer layer 101, and a display element layer including first to third display elements electrically connected to the pixel circuit may be disposed above the pixel circuit. In addition, the pixel circuit may include the thin-film transistor 120 and a capacitor Cst. That the first to third display elements are electrically connected to the pixel circuit may mean that pixel electrodes 211, 213, and 215 of the first to third display elements are electrically connected to the thin-film transistor 120.

The thin-film transistor 120 may include a semiconductor layer 121 including amorphous silicon, polycrystalline silicon, or an organic semiconductor material, a gate electrode 123, a source electrode 125, and a drain electrode 127.

The semiconductor layer 121 may be disposed on the buffer layer 101 and may include an oxide silicon, amorphous silicon or polysilicon. As an example, the semiconductor layer 121 may include an oxide of at least one material selected from the group including indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In addition, the semiconductor layer 121 may include a Zn oxide-based material. For example, the semiconductor layer 121 may include Zn oxide, In—Zn oxide, Ga—In—Zn oxide, etc. In addition, the semiconductor layer 121 may include an In—Ga—Zn—O (IGZO), In—Sn—Zn—O (ITZO), or In—Ga—Sn—Zn—O (IGTZO) semiconductor, in which metals, such as indium (In), gallium (Ga), and stannum (Sn), are contained in ZnO. The semiconductor layer 121 may include a channel region, and a source region and a drain region disposed on both sides of the channel region.

The gate electrode 123 may be disposed above the semiconductor layer 121 so that at least a portion of the gate electrode 123 overlaps the semiconductor layer 121. The gate electrode 123 may include various conductive materials including molybdenum (Mo), aluminum (Al), copper (Cu), titanium (Ti), etc. and may have various layered structures. For example, the gate electrode 123 may include a Mo layer and an Al layer, or may have a multi-layered structure including Mo/Al/Mo layers.

The source electrode 125 and the drain electrode 127 may also include various conductive materials including Mo, Al, Cu, Ti, etc. and may have various layered structures. For example, the source electrode 125 and the drain electrode 127 may each include a Ti layer and an Al layer, or may have a multi-layered structure including Ti/Al/Ti layers. Each of the source electrode 125 and the drain electrode 127 may be connected to the source region or drain region of the semiconductor layer 121 through contact holes.

In order to insulate the semiconductor layer 121 from the gate electrode 123, a gate insulating layer 103 including an inorganic material, such as silicon oxide, silicon nitride, or silicon oxynitride, may be disposed between the semiconductor layer 121 and the gate electrode 123. In addition, a first interlayer insulating layer 105 having a certain dielectric constant may be disposed on the gate electrode 123, and the first interlayer insulating layer 105 may be an insulating layer including an inorganic material, such as silicon oxide, silicon nitride, or silicon oxynitride. The source electrode 125 and the drain electrode 127 may be disposed on the first interlayer insulating layer 105. The insulating layer (film) including the inorganic material may be formed through chemical vapor deposition (CVD) or atomic layer deposition (ALD). This may also be applied to embodiments described below and their modifications.

The capacitor Cst may include a first electrode CE1 and a second electrode CE2. The first electrode CE1 and the second electrode CE2 overlap each other with the first interlayer insulating layer 105 interposed between the first electrode CE1 and the second electrode CE2 to form a capacitance. The first interlayer insulating layer 105 functions as a dielectric layer of the capacitor Cst.

The first electrode CE1 may be disposed on the same layer as the gate electrode 123. The first electrode CE1 may include the same material as the gate electrode 123. For example, the first electrode CE1 may include various conductive materials including, for example, molybdenum (Mo), aluminum (Al), copper (Cu), and titanium (Ti) and may have various layered structures (e.g., a multi-layered structure including Mo/Al/Mo layers). The second electrode CE2 may be disposed on the same layer as the source electrode 125 and the drain electrode 127. The second electrode CE2 may include the same material as the source electrode 125 and the drain electrode 127. For example, the second electrode CE2 may include various conductive materials including, for example, molybdenum (Mo), aluminum (Al), copper (Cu), and titanium (Ti) and may have various layered structures (e.g., a multi-layered structure including Ti/Al/Ti layers).

A second interlayer insulating layer 107 may be disposed on the second electrode CE2, the source electrode 125, and the drain electrode 127. The second interlayer insulating layer 107 may be an insulating layer including an inorganic material, such as silicon oxide, silicon nitride, and/or silicon oxynitride.

A planarization layer 109 may be disposed on the thin-film transistor 120. When an organic light-emitting element, as an example of the first to third display elements, is disposed on the thin-film transistor 120, the planarization layer 109 may generally planarize an upper portion of a protective layer covering the thin-film transistor 120. For example, the planarization layer 109 may include a general-purpose polymer, such as benzocyclobutene (BCB), polyimide (PI), hexamethyldisiloxane (HMDSO), polymethylmethacrylate (PMMA), or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or a combination thereof.

The first to third display elements may be disposed on the planarization layer 109. The first to third display elements may be organic light-emitting elements having the pixel electrodes 211, 213, and 215, an opposite electrode 230, and an intermediate layer 220 interposed between the pixel electrodes 211, 213, 215 and the opposite electrode 230 and including an emission layer.

In an embodiment, the first to third display elements may include a first pixel electrode 211, a second pixel electrode 214, a third pixel electrode 215, an opposite electrode 230 corresponding to the first to third pixel electrodes 211 to 215, and an intermediate layer 220 between the first to third pixel electrodes 211 to 215 and the opposite electrode 230. In addition, the intermediate layer 220 may include a first color emission layer that emits light having a wavelength belonging to a first wavelength band. For example, the first wavelength band may be about 450 nm to about 495 nm and the first color may be blue, but the present disclosure is not limited thereto.

Each of the pixel electrodes 211, 213, and 215 of the first to third display elements contacts one of the source electrode 125 and the drain electrode 127 through an opening (contact hole) formed in the planarization layer 109 and the second interlayer insulating layer 107 and is electrically connected to the thin-film transistor 120. The pixel electrodes 211, 213, and 215 may be (semi-)light-transmitting electrodes or reflective electrodes. In some embodiments, each of the pixel electrodes 211, 213, and 215 may include a reflective layer including Ag, Mg, Al, Pt, Pd, Au, Ni, Nd, Ir, Cr, or a combination thereof, and a transparent or translucent electrode layer formed on the reflective layer. The transparent or translucent electrode layer may include at least one selected from the group including indium tin oxide (ITO), indium zinc oxide (IZO), zinc oxide (ZnO), indium oxide (In₂O₃), indium gallium oxide (IGO), and aluminum zinc oxide (AZO). In addition, each of the pixel electrodes 211, 213, and 215 may have a stacked structure including ITO/Ag/ITO layers.

A pixel-defining layer 110 may be disposed on the planarization layer 109. The pixel-defining layer 110 may define a pixel (or emission area) by having an opening corresponding to each sub-pixel. The opening of the pixel-defining layer 110 is formed to expose at least a portion of each of the pixel electrodes 211, 213, and 215. For example, the pixel-defining layer 110 may be disposed between the first display element and the second display element, between the second display element and the third display element, and between the first display element and the third display element.

The pixel-defining layer 110 may increase the distance between the edges of the pixel electrodes 211, 213, and 215 and the opposite electrode 230 disposed on the pixel electrodes 211, 213, and 215, thereby preventing arcs, etc. from occurring at the edges of the pixel electrodes 211, 213, and 215. The pixel-defining layer 110 may include one or more organic insulating materials selected from the group including polyamide, polyimide, acrylic resin, benzocyclobutene, and phenol resin and may be formed by a method, such as spin coating.

The intermediate layer 220 of the first to third display elements may include a low-molecular material or a high-molecular material. When the intermediate layer 220 includes a low-molecular material, the intermediate layer 220 may have a stacked structure comprising a single or multi-layered structure, in which a hole injection layer (HIL), a hole transport layer (HTL), an emission layer (EML), an electron transport layer (ETL), and electron injection layer (EIL), and may be formed by vacuum deposition. When the intermediate layer 220 includes a high-molecular material, the intermediate layer 220 may have a structure including an HTL and an EML. In this case, the HTL may include PEDOT, and the EML may include a high-molecular material, such as poly-phenylene vinylene (PPV) or polyfluorene. The intermediate layer 220 may be formed by screen printing, inkjet printing, deposition, laser induced thermal imaging (LITI), or the like. The intermediate layer 220 is not necessarily limited thereto and may have various structures.

In an embodiment, the intermediate layer 220 may include a layer that is integrally formed as a single body across the first pixel electrode 211 of the first display element to the third pixel electrode 215 of the third display element. However, if necessary, the intermediate layer 220 may include a layer patterned to correspond to each of the first to third pixel electrodes 211 to 215. In either case, the intermediate layer 220 includes a first color emission layer. The first color emission layer may be integrally formed as a single body across the first pixel electrode 211 to the third pixel electrode 215, or may be patterned to correspond to each of the first pixel electrode 211 to the third pixel electrode 215, if necessary. The first color emission layer may emit light having a wavelength belonging to the first wavelength band, for example, light having a wavelength belonging to about 450 nm to about 495 nm.

The opposite electrode 230 shared by the first to third display elements is disposed on a display area. As an example, the opposite electrode 230 may include an integrated layer to cover the entire display area and may be disposed on the display area. In other words, the opposite electrode 230 may be integrally formed as one body with respect to the plurality of first to third display elements and correspond to the plurality of pixel electrodes 211, 213, and 215. In this case, the opposite electrode 230 may cover the display area and may be formed to extend to a portion of a non-display area outside the display area. Or, the opposite electrode 230 may be patterned to correspond to each of the plurality of pixel electrodes 211, 213, and 215.

The opposite electrode 230 may be a light-transmitting electrode or a reflective electrode. In some embodiments, the opposite electrode 230 may be a transparent or translucent electrode and may include a metal having a low work function, which comprises Li, Ca, LiF/Ca, LiF/Al, Al, Ag, Mg, and a combination thereof. In addition, the opposite electrode may further include a transparent conductive oxide (TCO) layer, such as ITO, IZO, ZnO, or In₂O₃.

The organic light-emitting elements may be easily damaged by moisture or oxygen from the outside, and thus may be protected by an encapsulation layer 130 covering the organic light-emitting elements. The encapsulation layer 130 includes at least one organic encapsulation layer and at least one inorganic encapsulation layer. For example, the encapsulation layer 130 may include a first inorganic encapsulation layer 131, an organic encapsulation layer 133, and a second inorganic encapsulation layer 135.

The first inorganic encapsulation layer 131 may cover the opposite electrode 230 and may include silicon oxide, silicon nitride, or silicon trioxynitride. Other layers (not shown), such as a capping layer, may be disposed between the first inorganic encapsulation layer 131 and the opposite electrode 230. Because the first inorganic encapsulation layer 131 is formed on various elements disposed below the first inorganic encapsulation layer 131, the upper surface of the first inorganic encapsulation layer 131 is not flat, and thus, the organic encapsulation layer 133 may be formed to cover the first inorganic encapsulation layer 131 to flatten the upper surface thereof. The organic encapsulation layer 133 may include one or more materials selected from the group including polyethylene terephthalate, polyethylene naphthalate, polycarbonate, polyimide, polyethylene sulfonate, polyoxymethylene, polyarylate, and hexamethyldisiloxane. The second inorganic encapsulation layer 135 is disposed to cover the organic encapsulation layer 133 and may include silicon oxide, silicon nitride, or silicon trioxynitride, etc.

Even if cracks occur within the encapsulation layer 130 through the multi-layered structure described above, such cracks may be prevented from propagating between the first inorganic encapsulation layer 131 and the organic encapsulation layer 420, or between the organic encapsulation layer 133 and the second inorganic encapsulation layer 135. This can prevent or minimize the formation of pathways through which moisture or oxygen from the outside may penetrate into the interior.

Second and third quantum dot layers 323 and 333, a light-transmitting layer 313, an adhesive layer 30, and first to third color filter layers 311, 321, and 331 may be disposed on the encapsulation layer 130. An upper substrate 400 may be disposed on the first to third color filter layers 311, 321, and 331. The first to third color filter layers 311 to 331 corresponding to the first to third pixels PX1 to PX3 are disposed on a first surface of the upper substrate 400. In this case, the “first surface” refers to a surface (lower surface) toward the display unit 10 where the first to third color filter layers 311, 321, and 331 are disposed. The first color filter layer 311 to the third color filter layer 331 may overlap the first pixel electrode 211 (or emission layer) of the first display element to the third pixel electrode 215 (or emission layer) of the third display element when viewed in a direction (the z-axis direction) perpendicular to the lower substrate 100 of the display unit 10 or the upper substrate 400. Accordingly, the first to third color filter layers 311 to 331 may filter light emitted from the first to third display elements, respectively.

First to third color filter portions 310 to 330 may include the first to third color filter layers 311 to 331 disposed on the first surface, which is the lower surface of the upper substrate 400, the light-transmitting layer 313 disposed on the first color filter layer 311, the second color quantum dot layer 323 disposed on the second color filter layer 321, and the third color quantum dot layer 333 disposed on the third color filter layer 331. However, the present disclosure is not limited thereto. In an embodiment, the first to third color filter layers 311 to 331 may be disposed on the encapsulation layer 130, and the light-transmitting layer 313, the second color quantum dot layer 323, and the third color quantum dot layer 333 may be disposed on the first to third color filter layers 311 to 331, respectively.

In an embodiment, the first color filter portion 310 may have the first color filter layer 311 and the light-transmitting layer 313, the second color filter portion 320 may have the second color filter layer 321 and the second color quantum dot layer 323, and the third color filter portion 330 may have the third color filter layer 331 and the third color quantum dot layer 333.

The first color filter layer 311 may allow only light having a wavelength ranging from about 450 nm to about 495 nm to pass therethrough, the second color filter layer 321 may allow only light having a wavelength ranging from about 495 nm to about 570 nm to pass therethrough, and the third color filter layer 331 may allow only light having a wavelength ranging from about 630 nm to about 780 nm to pass therethrough. The first to third color filter layers 311 to 331 may reduce external light reflection in the display device DV.

For example, when external light reaches the first color filter layer 311, only light having a preset wavelength as described above passes through the first color filter layer 311, and light having other wavelengths is absorbed by the first color filter layer 311. Therefore, of the external light incident to the display device DV, only the light having the preset wavelength as described above passes through the first color filter layer 311, and the light passing through the first color filter layer 311 may be reflected from the opposite electrode 230 or the first pixel electrode 211 of the first display element and is emitted again to the outside. Ultimately, because only some of the external light incident to the display device DV where the first pixel PX1 is disposed is reflected to the outside, external light reflection may be reduced. This description may be equally applied to the second color filter layer 321 and the third color filter layer 331.

The second color quantum dot layer 323 may convert light, which has a wavelength belonging to a first wavelength band and is generated by the intermediate layer 220 of the second display element, into light having a wavelength belonging to a second wavelength band. For example, when light having a wavelength ranging from about 450 nm to about 495 nm is generated by the intermediate layer 220 of the second display element, the second color quantum dot layer 323 may convert the light into light having a wavelength ranging from about 495 nm to about 570 nm. Accordingly, the light having a wavelength ranging from about 495 nm to about 570 nm is emitted to the outside from the second pixel PX2.

The third color quantum dot layer 333 may convert light, which has a wavelength belonging to the first wavelength band and is generated by the intermediate layer 220 of the third display element, into light having a wavelength belonging to a third wavelength band. For example, when light having a wavelength of about 450 nm to about 495 nm is generated by the intermediate layer 220 of the third display element, the third color quantum dot layer 333 may convert the light into light having a wavelength ranging from about 630 nm to about 780 nm. Accordingly, the light having a wavelength ranging from about 630 nm to about 780 nm is emitted to the outside from the third pixel PX3.

Each of the second color quantum dot layer 323 and the third color quantum dot layer 333 may have quantum dots dispersed within a resin.

The sizes of the quantum dots may be several nanometers, and the wavelength of light after conversion varies depending on the particle sizes of the quantum dots. In other words, the quantum dots may control the color of emitted light depending on the particle sizes of the quantum dots, and accordingly, the quantum dots may emit light having different colors, such as blue, red, and green. The particle sizes of the quantum dots may have a full width of half maximum (FWHM) of the emission wavelength spectrum of about 45 nm or less, preferably about 40 nm or less, more preferably about 30 nm or less, and within this range, color purity or color reproducibility may be improved. In addition, because light emitted through the quantum dots is emitted in all directions, an optical viewing angle may be improved. In addition, the shapes of the quantum dots are not particularly limited to those commonly used in the art. As examples, quantum dots in the form of spherical, pyramidal, multi-arm, or cubic nanoparticles, nanotubes, nanowires, nanofibers, nanoplate-shaped particles, etc. may be used. In addition, the quantum dots may include semiconductor materials, such as cadmium sulfide (CdS), cadmium telluride (CdTe), zinc sulfide (ZnS), or indium phosphide (InP).

The resin included in the second color quantum dot layer 323 and the third color quantum dot layer 333 may be any light-transmitting material. For example, polymer resins, such as silicone resin, epoxy resin, acrylic, BCB, and HMDSO, may be used as materials for forming the second color quantum dot layer 323 and the third color quantum dot layer 333.

The first color filter portion 310 may not include a quantum dot layer but may include the light-transmitting layer 313. For example, the first to third display elements are disposed between the first to third pixel electrodes 211 to 215 and the opposite electrode 230 and may include the intermediate layer 220 including the first color emission layer that emits light having a wavelength belonging to the first wavelength band. In this case, the first pixel PX1 emits light having a wavelength belonging to the first wavelength band, which is generated by the intermediate layer 220, to the outside without converting the wavelength. Accordingly, because the first pixel PX1 does not require a quantum dot layer, the first color filter portion 310 may include the light-transmitting layer 313 formed of a light-transmitting resin instead of a quantum dot layer.

The light-transmitting layer 313 may include scattering particles. The scattering particles may reduce the luminance ratio between the front and side of light emitted from a pixel. In each pixel, light generated from the display element passes through a filter portion and is emitted to the outside. This results in a higher luminance at the front and a relatively lower luminance at the side, creating the luminance ratio between the front and the side. This may cause performance degradation, such as a reduced viewing angle or distorted color coordinates. In the display device DV according to an embodiment, the light-transmitting layer 313 includes scattering particles, and thus, light passing through the light-transmitting layer 313 is scattered by the scattering particles thereby reducing the luminance ratio between the front and the side.

An adhesive layer 30 may be disposed between the first to third color filter layers 311, 321, and 331 and the second and third color quantum dot layers 323, 333 as well as the light-transmitting layer 313. For example, the adhesive layer 30 may be an optical clear adhesive (OCA), but is not necessarily limited thereto. In addition, the adhesive layer 30 may include a filler (not shown). The filler may be between the display unit 10 and the first to third color filter portions 310 to 330 including the second and third quantum dot layers 323, 333, the light-transmitting layer 313 and the first to third color filter layers 311, 321 and 331, and may act as a buffer against external pressure. The filler may include an organic material, such as methyl silicone, phenyl silicone, polyimide, a urethane-based resin as an organic sealant, an epoxy-based resin, an acrylic resin, or the filter may include an inorganic material, such as silicon as an inorganic sealant. But the present disclosure is not limited thereto. In an embodiment, the adhesive layer 30 may be omitted.

Partition walls 600 may be disposed between each of two adjacent color filter layers including the first color filter layer 311, the second color filter layer 321, and the third color filter layer 331. The partition walls 600 define first to third color regions in the spacing areas between adjacent partition walls 600, and the first to third color regions correspond to the first to third pixels PX1 to PX3, respectively.

The partition walls 600 may be patterned to correspond to a non-emission area of the display unit 10 and function as a light-blocking layer. In other words, light may be emitted to the outside only through the first to third color regions, which are regions where the partition walls 600 are not formed on an upper portion of a display element layer of the display unit 10.

The partition walls 600 may include a material (photoresist) that causes chemical changes when irradiated with light. For example, the partition walls 600 may include aromatic bis-azide, methacrylic acid ester, cinnamic acid ester, or the like as a negative photoresist and may include polymethyl methacrylate, polybutene-1-sulfone, or the like as a positive photoresist. However, the present disclosure is not limited thereto. The partition walls 600 may include a black matrix, black pigment, or metal material to function as a light-blocking layer and may include a reflective material, such as Al or Ag, to increase light efficiency.

The first to third color filter layers 311 to 331 are formed between the partition walls 600 to correspond to the first to third pixels PX1 to PX3, respectively. For example, the first to third color filter layers 311, 321, and 331 may be formed through an inkjet process, but are not limited thereto.

In an embodiment, a bank layer 501 may be disposed between the light-transmitting layer 313, the second color quantum dot layer 323, and the third color quantum dot layer 333. In other words, the light-transmitting layer 313, the second color quantum dot layer 323, and the third color quantum dot layer 333 may be disposed between bank layers 501 spaced apart from each other. The bank layer 501 may include an inorganic material. For example, the bank layer 501 may include at least one of silicon nitride (SiNₓ) or silicon oxide (SiOₓ).

A reflective layer 502 may be arranged to surround at least a portion of the bank layer 501. For example, the reflective layer 502 may be disposed on the side surface of the bank layer 501. The reflective layer 502 may be disposed to contact the side surface of the bank layer 501. The reflective layer 502 may be disposed to be in contact with the side surface of the bank layer 501 to reflect light emitted from a display element toward the reflective layer 502, thereby increasing the light efficiency of the display device DV. The reflective layer 502 may include metal. For example, the reflective layer 502 may include at least one of aluminum (Al), silver (Ag), or titanium (Ti).

A first inorganic insulating layer IL1 may be disposed on the bank layer 501, the reflective layer 502, the light-transmitting layer 313, the second color quantum dot layer 323, and the third color quantum dot layer 333. The adhesive layer 30 may be disposed on the first inorganic insulating layer IL1.

In the process of forming the bank layer 501 and the reflective layer 502 on the side surface of the bank layer 501, the liquid repellency of the upper surface of the bank layer 501 may be decreased. The process of forming the reflective layer 502 on the side surface of the bank layer 501 may include depositing a material for forming a reflective layer (hereinafter, referred to as a reflective layer forming material) on the bank layer 501, and forming the reflective layer 502 disposed on the side surface of the bank layer 501 by anisotropically dry-etching a portion of the reflective layer forming material disposed parallel to the substrate 100. In other embodiments, the process of forming the reflective layer 502 on the side surface of the bank layer 501 may include depositing a reflective layer forming material on the bank layer 501, depositing a photoresist on at least a portion of the reflective layer forming material, wet-etching a portion of the reflective layer forming material on which the photoresist is not disposed, and removing the photoresist. The process of forming the reflective layer 502 on the side surface of the bank layer 501 may include performing a dry etching process or a wet etching process and removing the photoresist, and this process may result in decreasing the liquid repellency of the upper surface of the bank layer 501. As the liquid repellency of the upper surface of the bank layer 501 decreases, in the process of depositing materials for forming the light-transmitting layer 313, the second color quantum dot layer 323, or the third color quantum dot layer 333 in the a spacing area between the adjacent bank layers 501 using an inkjet process, there may be an issue of the materials for forming the light-transmitting layer 313, the second color quantum dot layer 323, and the third color quantum dot layer 333 being adhered to and remaining on the upper surface of the bank layer 501.

In an embodiment, a length t1 of the bank layer 501 and the reflective layer 502 in a direction (e.g., an x direction or −x direction) parallel to the substrate may be 1 μm or less. As the bank layer 501 and the reflective layer 502 together have the length t1 of 1 μm or less in the direction (e.g., the x direction or −x direction) parallel to the substrate 100, when materials for forming the light-transmitting layer 313, the second color quantum dot layer 323, or the third color quantum dot layer 333 are formed, by using an inkjet process, in a spacing area where two adjacent bank layers 501 or two adjacent reflective layers 502 are spaced apart from each other, the materials for forming the light-transmitting layer 313, the second color quantum dot layer 323, and the third color quantum dot layer 333, which contain drops of several μm in size, may be prevented from adhering to and remaining on the upper surfaces of the bank layer 501 and the reflective layer 502. In addition, as the bank layer 501 and the reflective layer 502 together have the length t1 of 1 μm or less in the direction (e.g., the x direction or −x direction) parallel to the substrate 100, it is possible to prevent the materials for forming the light-transmitting layer 313, the second color quantum dot layer 323, and the third color quantum dot layer 333 from adhering to upper surface of the bank layer 501 when formed using an inkjet process, regardless of the liquid repellency of the upper surface of the bank layer 501 being reduced.

In addition, as the bank layer 501 and the reflective layer 502 together have the length t1 of 1 μm or less in the direction (e.g., the x direction or −x direction) parallel to the substrate 100, the aperture ratio of the bank layer 501 may be increased and the brightness and quality of the display device DV may be improved.

While the upper surface of the bank layer 501 according to the embodiment shown in FIG. 5 may be a flat surface, the upper surface of the bank layer 501 according to the embodiment shown in FIG. 6 may be an inclined surface. The process of manufacturing the bank layer 501 shown in FIG. 5 may be different from the process of manufacturing the bank layer 501 shown in FIG. 6, and accordingly, the shape of the upper surface of the bank layer 501 shown in FIG. 5 may be different from the shape of the upper surface of the bank layer 501 shown in FIG. 6. The process of manufacturing the bank layer 501 will be described in more detail below.

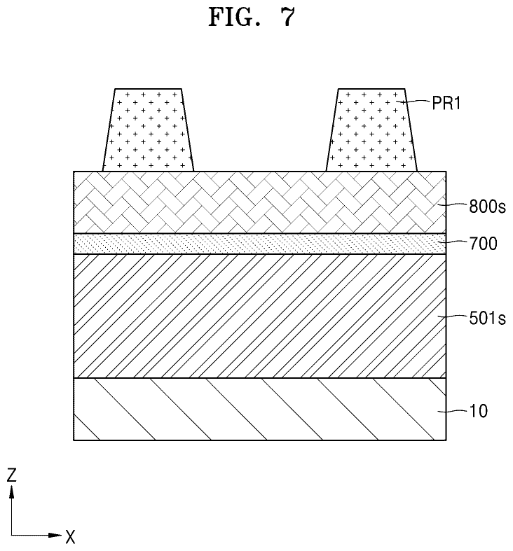

FIGS. 7 to 13 are cross-sectional views schematically illustrating a method of manufacturing the display device shown in FIG. 5, according to an embodiment.

Referring to FIGS. 7 to 13, in an embodiment, the method of manufacturing the display device may include preparing a substrate 100 (see FIG. 5), depositing a material 501s for forming a bank layer (hereinafter, referred to as a bank layer forming material 501s) on the substrate 100, forming a bank layer 501 by patterning the bank layer forming material 501s, depositing a reflective layer forming material 502s on the bank layer 501, and forming a reflective layer 502 disposed on the side surface of the bank layer 501 by etching at least a portion of the reflective layer forming material 502s.

Referring to FIG. 7, the bank layer forming material 501s may be disposed on a display unit 10 including the substrate 100. The bank layer forming material 501s may include an inorganic material. For example, the bank layer forming material 501s may include at least one of silicon nitride (SiNₓ) or silicon oxide (SiOₓ). A hard mask 700 may be disposed on the bank layer forming material 501s. The hard mask 700 may include metal. For example, the hard mask 700 may include aluminum (Al). A material 800s for forming a sacrificial layer (hereinafter, referred to as a sacrificial layer forming material 800s) may be disposed on the hard mask 700. A first photoresist PR1 may be disposed on at least a portion of the sacrificial layer forming material 800s.

A sacrificial layer 800 may be formed by etching a portion of the sacrificial layer forming material 800s on which the first photoresist PR1 is not disposed. The sacrificial layer 800 may include an inorganic material. For example, the sacrificial layer 800 may include silicon nitride (SiNₓ).

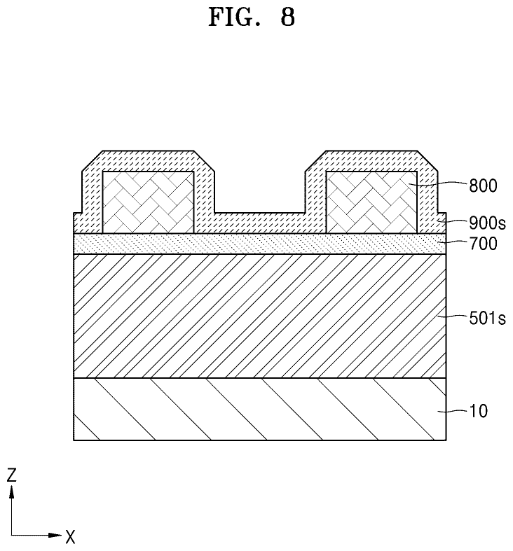

Referring to FIG. 8, a material 900s for forming a sidewall (hereinafter, referred to as a sidewall forming material 900s) may be disposed on the sacrificial layer 800. The sidewall forming material 900s may include an inorganic material. The sidewall forming material 900s may include silicon oxide (SiOₓ).

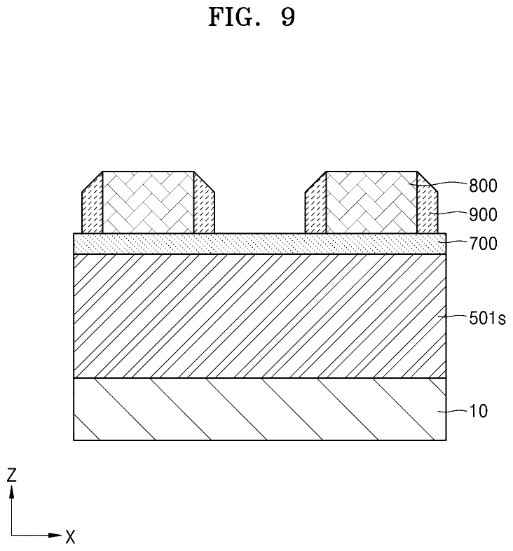

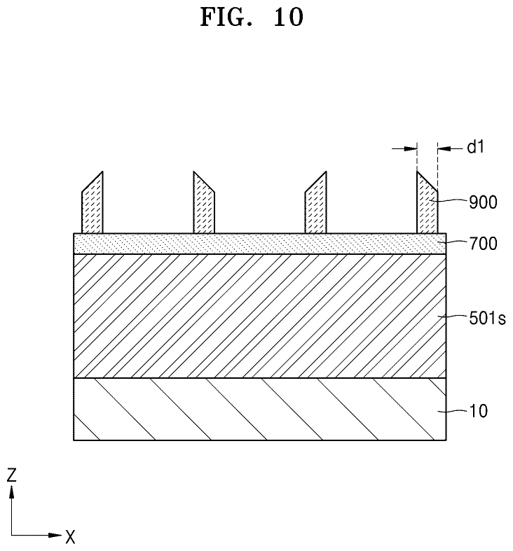

Referring to FIGS. 9 and 10, a sidewall 900 may be formed by etching at least a portion of the sidewall forming material 900s. For example, the sidewall 900 may be formed by anisotropically etching a portion of the sidewall forming material 900s disposed parallel to the substrate 100. A length d1 of the sidewall 900 in a direction (e.g., an x direction or −x direction) parallel to the substrate 100 (see FIG. 5) may be 100 nm or less. Thereafter, the sacrificial layer 800 may be removed. The sacrificial layer 800 includes silicon nitride (SiNₓ), while the sidewall 900 includes silicon oxide (SiOₓ). Therefore, depending on the difference in dry etching rates according to the type of film, only the sacrificial layer 800 may be removed from a structure, in which the sacrificial layer 800 and the sidewall 900 are arranged.

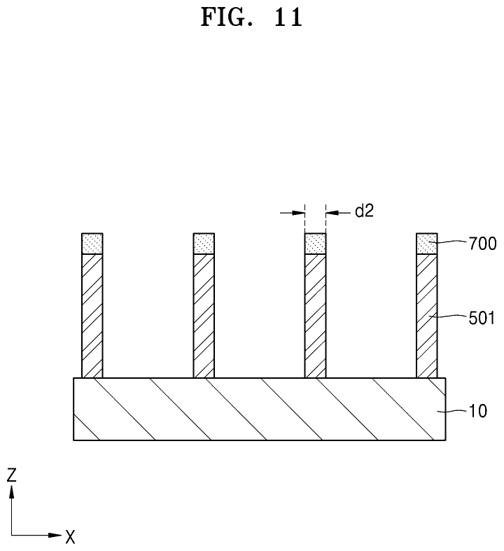

Referring to FIG. 11, the bank layer 501 may be formed by etching a portion of the bank layer forming material 501s on which the sidewall 900 is not disposed. The upper surface of the bank layer 501 may be provided as a flat surface. In the forming of the bank layer 501, the hard mask 700 may be disposed on the bank layer forming material 501s, and a portion of the hard mask 700 on which the sidewall 900 is not disposed may also be etched together with the bank layer forming material 501s. A length d2 of the bank layer 501 in the direction (e.g., the x direction or −x direction) parallel to the substrate 100 may be 200 nm or less.

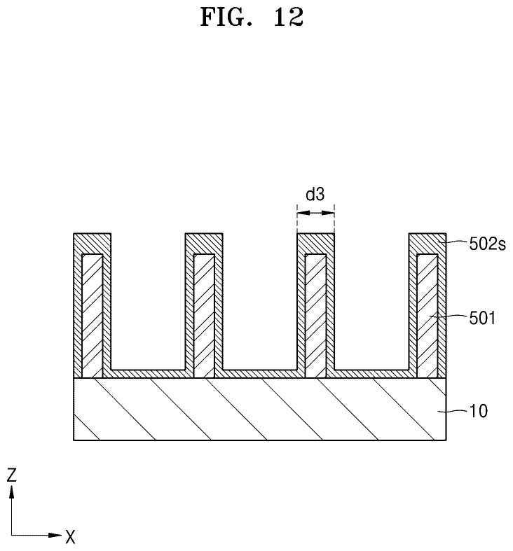

Referring to FIG. 12, the reflective layer forming material 502s may be disposed on the bank layer 501. The reflective layer forming material 502s may include metal. For example, the reflective layer forming material 502s may include at least one of aluminum (Al), silver (Ag), or titanium (Ti). The bank layer 501 and the reflective layer forming material 502s may together have a length d3 of 300 nm or less in the direction (e.g., the x direction or −x direction) parallel to the substrate 100.

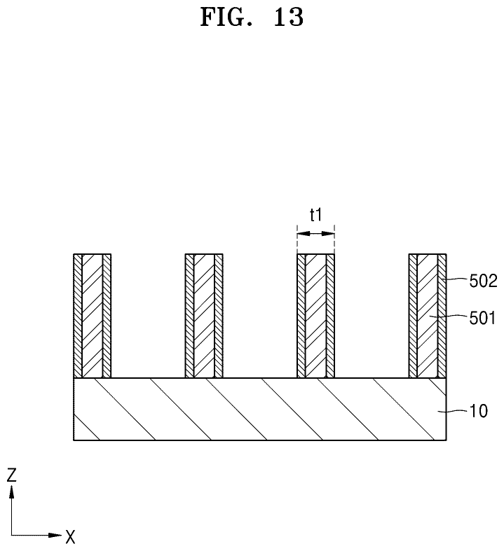

Referring to FIG. 13, the reflective layer 502 may be formed by anisotropically etching a portion of the reflective layer forming material 502s disposed parallel to the substrate 100. The reflective layer 502 may be disposed to contact the side surface of the bank layer 501. The bank layer 501 and the reflective layer 502 may together have a length t1 of 1 μm or less in the direction (e.g., the x direction or −x direction) parallel to the substrate 100. As an example, the length t1 of the sum of the bank layer 501 and the reflective layer 502 in the direction (e.g., the x direction or −x direction) parallel to the substrate 100 may be 300 nm or less. As the bank layer 501 and the reflective layer 502 together have a length t1 of 1 μm or less in the direction (e.g., the x direction or −x direction) parallel to the substrate 100, when materials for forming the light-transmitting layer 313 (see FIG. 5), the second color quantum dot layer 323 (see FIG. 5), or the third color quantum dot layer 333 (see FIG. 5) are formed, by using an inkjet process, in a spacing area where two adjacent bank layers 501 or two adjacent reflective layers 502 are spaced apart from each other, the materials for forming the light-transmitting layer 313, the second color quantum dot layer 323, and the third color quantum dot layer 333, which contain drops of several μm in size, may be prevented from adhering to and remaining on the upper surfaces of the bank layer 501 and the reflective layer 502. In addition, by increasing the aperture ratio of the bank layer 501, the brightness and quality of the display device may be improved.

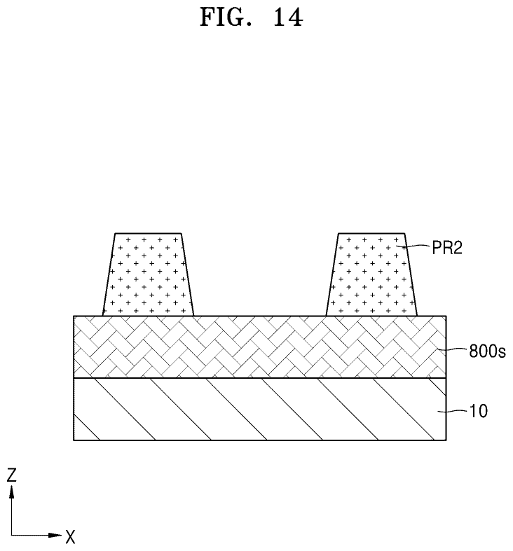

FIGS. 14 to 19 are cross-sectional views schematically illustrating a method of manufacturing the display device shown in FIG. 6, according to an embodiment.

Referring to FIGS. 14 to 19, in an embodiment, the method of manufacturing the display device may include preparing a substrate 100 (see FIG. 6), forming a sacrificial layer 800 on the substrate 100, forming a bank layer 501 disposed on the side surface of the sacrificial layer 800, and forming a reflective layer 502 disposed on the side surface of the bank layer 501.

Referring to FIG. 14, a sacrificial layer forming material 800s may be disposed on a display unit 10 including the substrate 100. A second photoresist PR2 may be disposed on at least a portion of the sacrificial layer forming material 800s. The sacrificial layer forming material 800s may include an inorganic material. For example, the sacrificial layer forming material 800s may include silicon nitride (SiNₓ).

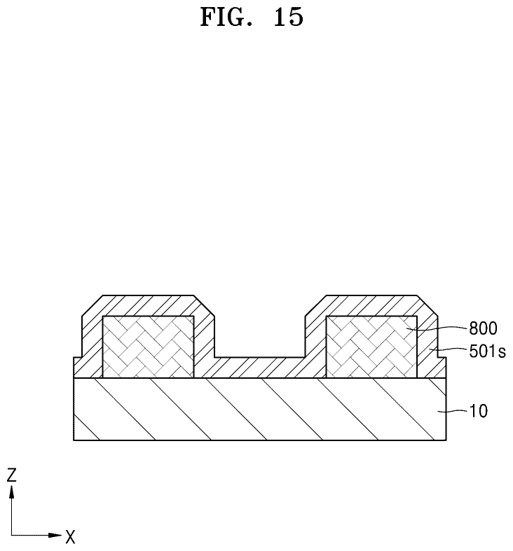

Referring to FIG. 15, the sacrificial layer 800 may be formed by etching a portion of the sacrificial layer forming material 800s on which the second photoresist PR2 is not disposed. A bank layer forming material 501s may be deposited on the sacrificial layer 800. The bank layer forming material 501s may include silicon oxide (SiOₓ).

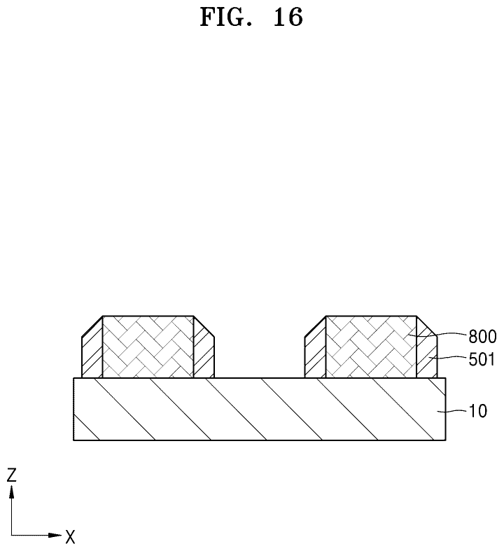

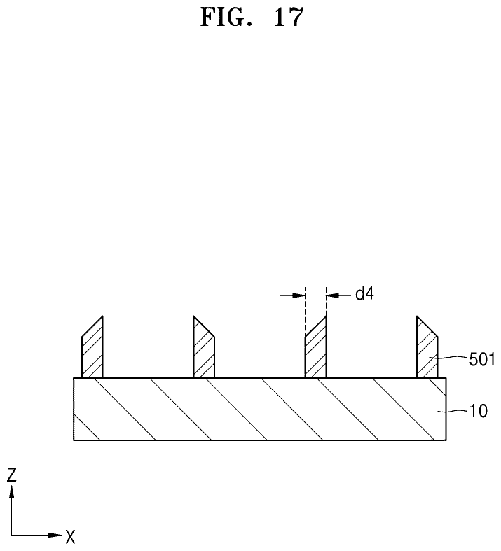

Referring to FIGS. 16 and 17, the bank layer 501 may be formed by anisotropically etching a portion of the bank layer forming material 800s parallel to the substrate 100. The bank layer 501 may have an inclined surface. Thereafter, the sacrificial layer 800 may be removed. Because the bank layer 501 includes silicon oxide (SiOₓ) and the sacrificial layer 800 includes silicon nitride (SiNₓ), only the sacrificial layer 800 may be removed from a structure, in which the sacrificial layer 800 and the bank layer 501 are arranged, depending on the difference in dry etching rates according to the type of film. A length d4 of the bank layer 501 in a direction (e.g., an x direction or −x direction) parallel to the substrate 100 may be 100 nm or less.

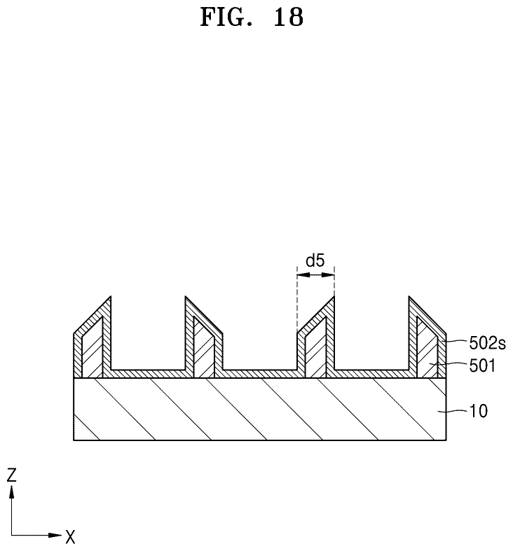

Referring to FIG. 18, a reflective layer forming material 502s may be deposited on the bank layer 501. The reflective layer forming material 502s may include metal. For example, The reflective layer forming material 502s may include at least one of aluminum (Al), silver (Ag), or titanium (Ti). The bank layer 501 and the reflective layer forming material 502s may together have a length d5 of 200 nm or less in the direction (e.g., the x direction or −x direction) parallel to the substrate 100.

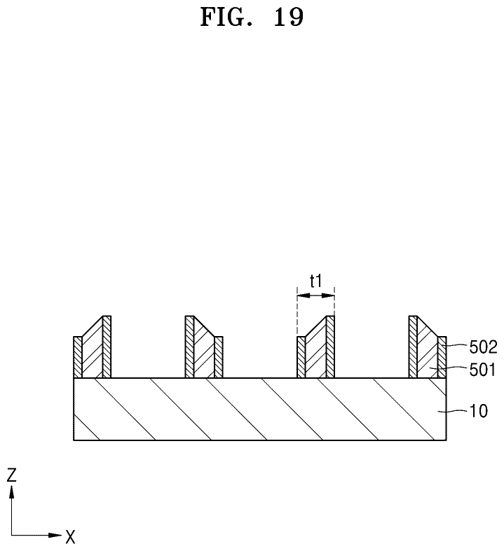

Referring to FIG. 19, the reflective layer 502 may be formed by anisotropically etching a portion of the reflective layer forming material 502s that is in contact with the upper surface of the bank layer 501 and the upper surface of the display unit 10. The bank layer 501 and the reflective layer 502 may together have a length of 200 nm or less in the direction parallel to the substrate 100.

In an embodiment, as the bank layer 501 and the reflective layer 502 together have a length t1 of 1 μm or less in the direction (e.g., the x direction or −x direction) parallel to the substrate 100, when materials for forming the light-transmitting layer 313 (see FIG. 5), the second color quantum dot layer 323 (see FIG. 5), or the third color quantum dot layer 333 (see FIG. 5) are formed, by using an inkjet process, in a spacing area where two adjacent bank layers 501 or two adjacent reflective layers 502 are spaced apart from each other, the materials for forming the light-transmitting layer 313, the second color quantum dot layer 323, and the third color quantum dot layer 333, which contain drops of several μm in size, may be prevented from adhering to and remaining on the upper surfaces of the bank layer 501 and the reflective layer 502. In addition, by increasing the aperture ratio of the bank layer 501, the brightness and quality of the display device may be improved.

According to the embodiments of the present disclosure as described above, a display device having improved quality and reliability and a method of manufacturing the display device may be implemented. Obviously, the scope of the present disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While the present disclosure has been described with reference to the drawings and embodiments thereof, it will be understood by those of ordinary skill in the art that various changes in form and details may be made thereto without departing from the spirit and scope of the present disclosure as set forth in the following claims.

What is claimed is:

1. A display device comprising:
a substrate;
a bank layer disposed on the substrate; and
a reflective layer disposed on a side surface of the bank layer and in contact with a light-transmitting layer, a second color quantum dot layer or a third color quantum dot layer,
wherein the bank layer and the reflective layer together have a length of 1 μm or less in a direction parallel to the substrate.

2. The display device of claim 1, wherein the reflective layer is in contact with the side surface of the bank layer.

3. The display device of claim 1, wherein the bank layer includes an inorganic material.

4. The display device of claim 3, wherein the bank layer includes at least one of silicon nitride (SiNₓ) or silicon oxide (SiOₓ).

5. The display device of claim 1, wherein the reflective layer includes metal.

6. The display device of claim 1, wherein the reflective layer includes at least one of aluminum (Al), silver (Ag), or titanium (Ti).

7. The display device of claim 1, wherein an upper surface of the bank layer is inclined.

8. A method of manufacturing a display device, the method comprising:
preparing a substrate;
depositing a bank layer forming material on the substrate;
forming a bank layer by patterning the bank layer forming material; depositing a reflective layer forming material on the bank layers;
forming a reflective layer disposed on a side surface of the bank layer by etching at least a portion of the reflective layer forming material; and
forming a light-transmitting layer, a second color quantum dot layer or a third color quantum dot layer in a spacing area between two adjacent reflective layers,
wherein the reflective layer is in contact with the light-transmitting layer, the second color quantum dot layer or the third color quantum dot layer, and
wherein the bank layer and the reflective layer together have a length of 1 μm or less in a direction parallel to the substrate.

9. The method of claim 8, wherein the forming the reflective layer by etching at least the portion of the reflective layer forming material comprises forming the reflective layer by anisotropically etching a portion of the reflective layer forming material, the portion of the reflective layer forming material being disposed parallel to the substrate.

10. The method of claim 8, wherein the forming the bank layer by patterning the bank layer forming material comprises:
disposing a hard mask on the bank layer forming material;
forming a sidewall on the hard mask; and
forming the bank layer by etching a portion of the bank layer forming material, the portion of the bank layer forming material not covered by the sidewall.

11. The method of claim 10, wherein the forming the bank layer by etching the portion of the bank layer forming material comprises etching a portion of the hard mask on which the sidewall is not disposed.

12. The method of claim 10, wherein the forming the sidewall on the hard mask comprises:
forming a sacrificial layer on the hard mask;
depositing a sidewall forming material on the sacrificial layer;
forming the sidewall by anisotropically etching a portion of the sidewall forming material, the portion of the sidewall forming material being disposed parallel to the substrate; and
removing the sacrificial layer.

13. The method of claim 12, wherein the forming the sacrificial layer on the hard mask comprises:
depositing a sacrificial layer forming material on the hard mask;
depositing a photoresist on at least a portion of the sacrificial layer forming material; and
forming the sacrificial layer by etching a portion of the sacrificial layer forming material, the photoresist being not disposed on the portion of the sacrificial layer forming material.

14. The method of claim 8, wherein the bank layer includes an inorganic material.

15. The method of claim 14, wherein the bank layer includes at least one of silicon nitride (SiNₓ) or silicon oxide (SiOₓ).

16. The method of claim 8, wherein the reflective layer includes at least one of aluminum (Al), silver (Ag), or titanium (Ti).

17. A method of manufacturing a display device, the method comprising:
preparing a substrate;
forming a sacrificial layer on the substrate;
forming a bank layer using the sacrificial layer;
forming a reflective layer disposed on a side surface of the bank layer; and
forming a light-transmitting layer, a second color quantum dot layer or a third color quantum dot layer in a spacing area between two adjacent reflective layers,
wherein the reflective layer is in contact with the light-transmitting layer, the second color quantum dot layer or the third color quantum dot layer, and
wherein the bank layer and the reflective layer together have a length of 1 μm or less in a direction parallel to the substrate.

18. The method of claim 17, wherein an upper surface of the bank layer is inclined.

19. The method of claim 17, wherein the forming the sacrificial layer on the substrate comprises:
depositing a sacrificial layer forming material on the substrate;
depositing a photoresist on at least a portion of the sacrificial layer forming material; and
forming the sacrificial layer by etching at least a portion of the sacrificial layer forming material, the photoresist being not disposed on the portion of the sacrificial layer forming material.

20. The method of claim 17, wherein the forming the bank layer comprises:
depositing a bank layer forming material on the sacrificial layer; and
forming the bank layer by anisotropically etching a portion of the bank layer forming material, the portion of the bank layer forming material being disposed parallel to the substrate.
